(19) United States
(12) Patent Application Publication
(10) Pub. No.: US 2023/0134799 A1
(43) Pub. Date: May 4, 2023

(54) METHOD FOR MANUFACTURING LIGHT-EMITTING DEVICE

(71) Applicant: NICHIA CORPORATION, Anan-shi (JP)

(72) Inventor: Hiroaki KAGEYAMA, Tokushima-shi (JP)

(73) Assignee: NICHIA CORPORATION, Anan-shi (JP)

(21) Appl. No.: 17/967,455

(22) Filed: Oct. 17, 2022

(30) Foreign Application Priority Data
Oct. 29, 2021 (JP) 2021-177467
Jun. 10, 2022 (JP) 2022-094309

(51) Int. Cl. H01L 33/22; H01L 33/00; H01L 33/50

(52) U.S. Cl. CPC H01L 33/22; H01L 33/50; H01L 33/0093; H01L 33/0095; H01L 2933/0041

(57) ABSTRACT

A method for manufacturing a light-emitting device includes preparing light-emitting elements, each including a semiconductor structure body that includes a first surface including recesses, a second surface, and a lateral surface. The method includes disposing the light-emitting elements on an adhesive sheet member so that the second surfaces face the sheet member and the lateral surfaces are covered with the sheet member. The method includes causing a first member to contact the first surfaces so that the first member is located inside the recesses and located between the sheet member and a second member in a state in which the second member is located on the first member. The first member includes a transmissive uncured resin member. The second member includes a wavelength conversion material and has a higher hardness than the uncured resin member. The method includes curing the first member, and removing the sheet member.

### CROSS-REFERENCE TO RELATED APPLICATIONS

This application is based upon and claims priority to Japanese Patent Application No.2021-177467, filed on Oct. 29, 2021, and Japanese Patent Application No.2022-094309, filed on Jun. 10, 2022, the entire contents of which are incorporated herein by reference.

### BACKGROUND

Embodiments relate to a method for manufacturing a light-emitting device.

JP-A 2016-149389 discusses a method for manufacturing a light-emitting device in which a light-emitting element is adhered to a support substrate, and a phosphor layer is formed by spraying phosphor particles or the like onto a semiconductor layer of the light-emitting element.

### SUMMARY

According to one aspect of the present invention, a method for manufacturing a light-emitting device includes preparing a plurality of light-emitting elements. Each of the plurality of light-emitting elements includes a semiconductor structure body. The semiconductor structure body includes a first surface including a plurality of recesses, a second surface positioned at a side opposite to the first surface, and a lateral surface connecting the first surface and the second surface. The method includes disposing the plurality of light-emitting elements on a sheet member so that the second surfaces of the plurality of light-emitting elements face the sheet member and so that the lateral surfaces of the plurality of light-emitting elements are covered with the sheet member. The sheet member is adhesive. The method includes causing a first member to contact the first surfaces of the plurality of light-emitting elements so that the first member is located inside the plurality of recesses and located between the sheet member and a second member in a state in which the second member is located on the first member. The first member includes an uncured resin member that is transmissive. The second member includes a wavelength conversion material and has a higher hardness than the uncured resin member. The method includes curing the first member, and removing the sheet member from the plurality of light-emitting elements.

### BRIEF DESCRIPTION OF THE DRAWINGS

FIG. 1 is a cross-sectional view showing a light-emitting module according to a first embodiment;

FIG. 2A is an enlarged top view showing a portion of a first surface of a semiconductor structure body shown in FIG. 1;

FIG. 2B is a top view showing the light-emitting module according to the first embodiment;

FIG. 3 is a flowchart showing a method for manufacturing the light-emitting module according to the first embodiment;

FIGS. 4A to 7C are cross-sectional views illustrating the method for manufacturing the light-emitting module according to the first embodiment;

FIG. 8 is a cross-sectional view illustrating a method for manufacturing a light-emitting module according to a reference example;

FIG. 9 is a cross-sectional view illustrating a method for manufacturing a light-emitting module according to a first modification of the first embodiment; and

FIG. 10 is a cross-sectional view showing a light-emitting module according to a second embodiment.

### DETAILED DESCRIPTION

Exemplary embodiments will now be described with reference to the drawings.

The drawings are schematic or conceptual, and the relationships between the thickness and width of portions, the proportional coefficients of sizes among portions, etc., are not necessarily the same as the actual values thereof. Furthermore, the dimensions and proportional coefficients may be illustrated differently among drawings, even for identical portions.

In the specification of the application and the drawings, components similar to those described in regard to a previously described drawing are marked with like reference numerals, and a detailed description is omitted as appropriate.

### First Embodiment

First, a first embodiment will be described.

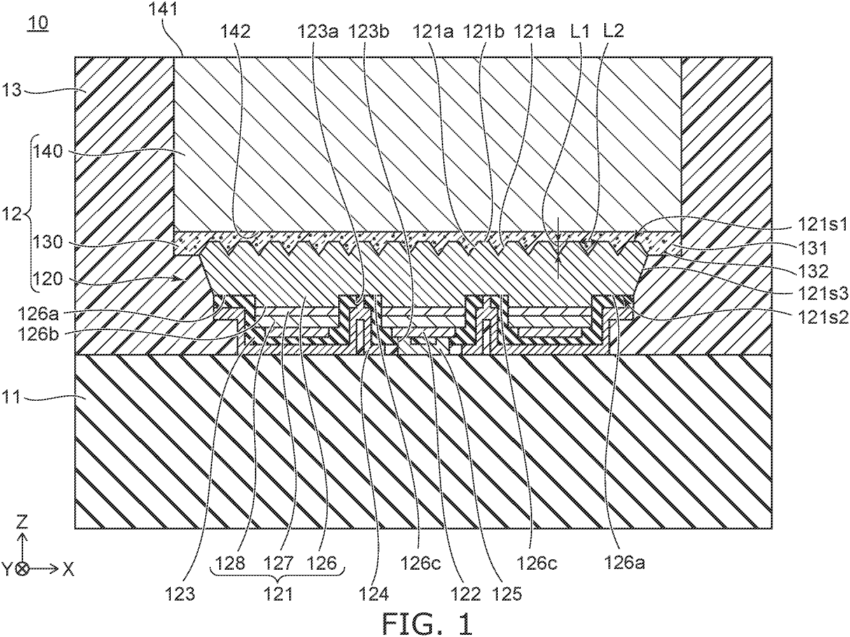

FIG. 1 is a cross-sectional view showing a light-emitting module 10 according to the embodiment.

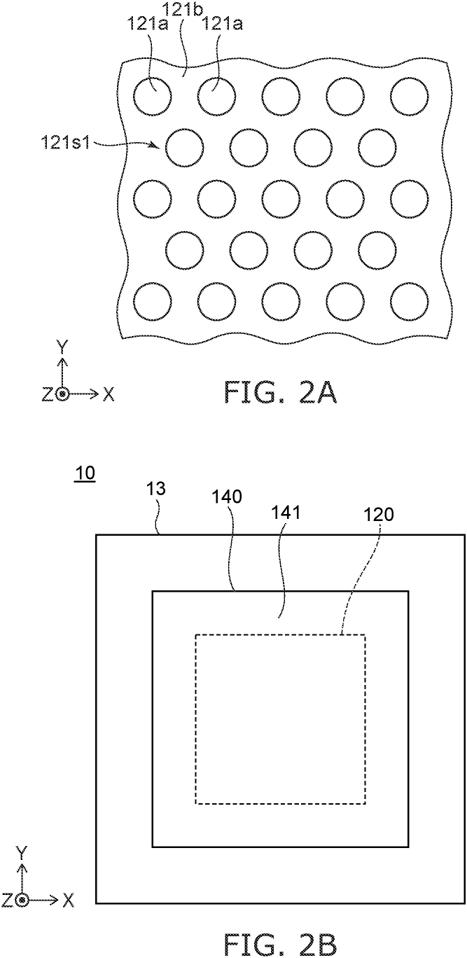

FIG. 2A is an enlarged top view showing a portion of a first surface 121s1 of a semiconductor structure body 121 shown in FIG. 1.

FIG. 2B is a top view showing the light-emitting module 10 according to the embodiment.

The light-emitting module 10 according to the embodiment includes a wiring substrate 11, a light-emitting device 12, and a resin member 13. The light-emitting device 12 includes a light-emitting element 120, a first member 130, and a second member 140. The components of the light-emitting module 10 will now be elaborated. An XYZ orthogonal coordinate system is used for easier understanding of the following description. Hereinbelow, the direction in which the light-emitting element 120, the first member 130, and the second member 140 are arranged is taken as a “Z-direction.” A direction orthogonal to the Z-direction is taken as an “X-direction,” and a direction orthogonal to the Z-direction and the X-direction is taken as a “Y-direction.” When describing the structure of the light-emitting module 10, among the Z-directions, the direction from the light-emitting element 120 toward the second member 140 is taken as the “upward direction,” and the opposite direction is taken as the “downward direction”; however, these directions are relative and are independent of the direction of gravity.

For example, the wiring substrate 11 includes an insulating layer and multiple interconnects located on the insulating layer. For example, the wiring substrate 11 has a flat plate shape. The upper surface and the lower surface of the wiring substrate 11 are substantially parallel to the X-Y plane.

The light-emitting element 120 is located on the wiring substrate 11. The light-emitting element 120 includes the semiconductor structure body 121, a light-reflective electrode 122, an insulating film 123, an n-side electrode 124, and a p-side electrode 125.

The semiconductor structure body 121 is, for example, a structure body in which multiple semiconductor layers made of a nitride semiconductor are stacked. Here, “nitride semiconductor” includes all compositions of semiconductors of the chemical formula InₓAl_{y}Ga_{1-x-y}N (0 ≤ x ≤ 1, 0 ≤ y ≤ 1, and x + y ≤ 1) for which the composition ratios x and y are changed within the ranges respectively. The semiconductor structure body 121 includes an n-side semiconductor layer 126, an active layer 127, and a p-side semiconductor layer 128 in this order downward from above.

The upper surface of the n-side semiconductor layer 126 corresponds to the upper surface of the semiconductor structure body 121. Hereinbelow, the upper surface of the semiconductor structure body is called the “first surface 121s1.” Multiple recesses 121a are provided in the first surface 121s1. A region 121b of the first surface 121s1 between the multiple recesses 121a is, for example, a region that is substantially parallel to the X-Y plane. The multiple recesses 121a are surrounded with the region 121b in a top-view.

The multiple recesses 121a are arranged in a staggered configuration in a top-view. However, the arrangement pattern of the multiple recesses 121a is not limited to such a pattern. For example, the multiple recesses 121a may be arranged in a matrix configuration.

As shown in FIGS. 1 and 2A, each recess 121a is substantially circular conic. A depth L1 of each recess 121a is not particularly limited. It is favorable for the depth L1 of each recess 121a to be, for example, not less than 0.5 µm and not more than 3 µm. A diameter L2 of each recess 121a is not particularly limited. It is favorable for the diameter L2 of each recess 121a to be, for example, not less than 1 µm and not more than 6 µm. However, the shape and size of each recess 121a is not particularly limited to the shapes and sizes described above. For example, each recess 121a may be a truncated pyramid, circular cone, polygonal pyramid, hemisphere, etc.

As shown in FIG. 1, the lower surface of the n-side semiconductor layer 126 includes an outer perimeter region 126a, a covered region 126b, and multiple contact regions 126c. The outer perimeter region 126a is within a constant range from the outer perimeter edge of the lower surface of the n-side semiconductor layer 126. The outer perimeter region 126a is substantially parallel to the X-Y plane. The covered region 126b is positioned inward of the outer perimeter region 126a. The covered region 126b is substantially parallel to the X-Y plane. The position of the covered region 126b in the Z-direction is lower than the position of the outer perimeter region 126a. Each contact region 126c is positioned inward of the outer perimeter edge of the covered region 126b. Each contact region 126c is substantially parallel to the X-Y plane. The positions of the contact regions 126c in the Z-direction are higher than the position of the covered region 126b and substantially the same as the position of the outer perimeter region 126a.

The active layer 127 covers substantially the entire region of the covered region 126b of the lower surface of the n-side semiconductor layer 126. The p-side semiconductor layer 128 covers substantially the entire region of the lower surface of the active layer 127. The active layer 127 and the p-side semiconductor layer 128 leave exposed the contact regions 126c and the outer perimeter region 126a of the lower surface of the n-side semiconductor layer 126.

The surface of the semiconductor structure body 121 positioned inward of the outer perimeter edge of the lower surface of the n-side semiconductor layer 126, i.e., the outer perimeter edge of the outer perimeter region 126a, is called a “second surface 121s2.” The second surface 121s2 is positioned at the side opposite to the first surface 121s1. A surface that is positioned between the first surface 121s1 and the second surface 121s2 and connected to the first and second surfaces 121s1 and 121s2 is called a “lateral surface 121s3.”

The light-reflective electrode 122 is located at the lower surface of the p-side semiconductor layer 128. The light-reflective electrode 122 covers at least a portion of the lower surface of the p-side semiconductor layer 128. The light-reflective electrode 122 contacts the p-side semiconductor layer 128. Thereby, the light-reflective electrode 122 is electrically connected to the p-side semiconductor layer 128. The light-reflective electrode 122 can include, for example, silver (Ag), aluminum (Al), nickel (Ni), titanium (Ti), platinum (Pt), an alloy that includes such a metal as a major component, etc.

The insulating film 123 is located below the semiconductor structure body 121 and the light-reflective electrode 122. The insulating film 123 partially covers the lower surface of the light-reflective electrode 122 and the second surface 121s2 of the semiconductor structure body 121. Multiple through-holes 123a that expose the multiple contact regions 126c of the n-side semiconductor layer 126 and a through-hole 123b that exposes the lower surface of the light-reflective electrode 122 are provided in the insulating film 123.

The insulating film 123 can include an insulating material such as silicon oxide (SiO₂), silicon nitride (SiN), etc. The insulating film 123 may have a single-layer structure or a multilayer structure.

The n-side electrode 124 is located below the insulating film 123. The n-side electrode 124 contacts the contact regions 126c of the n-side semiconductor layer 126 via the through-holes 123a. Thereby, the n-side electrode 124 is electrically connected to the n-side semiconductor layer 126. The n-side electrode 124 is electrically connected to one interconnect of the wiring substrate 11 via a conductive member. The conductive member can include, for example, a metal bump, solder, etc.

The p-side electrode 125 is located below the insulating film 123 and separated from the n-side electrode 124. The p-side electrode 125 contacts the light-reflective electrode 122 via the through-hole 123b. Thereby, the p-side electrode 125 is electrically connected to the p-side semiconductor layer 128. The p-side electrode 125 is electrically connected to another interconnect of the wiring substrate 11 via a conductive member.

The n-side electrode 124 and the p-side electrode 125 can include aluminum (Al), nickel (Ni), titanium (Ti), platinum (Pt), an alloy that includes such a metal as a major component, etc.

However, the configuration of the light-emitting element 120 is not limited to the configuration described above as long as the semiconductor structure body 121 is included and the multiple recesses 121a are provided in the first surface 121s1 of the semiconductor structure body 121. For example, the position at which the n-side semiconductor layer 126 and the n-side electrode 124 contact and the position at which the p-side semiconductor layer 128 and the light-reflective electrode 122 contact are not particularly limited to the positions shown in FIG. 1. It is sufficient for the n-side electrode 124 and the n-side semiconductor layer 126 to be electrically connected; one or more conductive members may be interposed between the n-side electrode 124 and the n-side semiconductor layer 126. It is sufficient for the p-side electrode 125 and the light-reflective electrode 122 to be electrically connected; one or more conductive members may be interposed between the p-side electrode 125 and the light-reflective electrode 122. The p-side electrode 125 may contact the p-side semiconductor layer 128 without including the light-reflective electrode 122 in the light-emitting element 120.

The second member 140 is located above the light-emitting element 120. For example, the second member 140 has a flat plate shape. The surfaces of the second member 140 include an upper surface 141 and a lower surface 142 positioned at the side opposite to the upper surface 141. The upper surface 141 and the lower surface 142 are substantially parallel to the X-Y plane.

According to the embodiment, when viewed along the Z-direction, the outer perimeter edge of the second member 140 is positioned outward of the outer perimeter edge of the first surface 121s1 of the light-emitting element 120. However, the outer perimeter of the second member 140 may align with the outer perimeter edge of the first surface 121s1 when viewed along the Z-direction.

The second member 140 is, for example, a sintered body of a wavelength conversion material. The wavelength conversion material performs a wavelength conversion of a portion of the light emitted by the light-emitting element 120 and emits light of a different light emission peak wavelength from the light emission peak wavelength of the light emitted by the light-emitting element 120. The light-emitting device 12 emits mixed light of the light emitted by the semiconductor structure body 121 and the light emitted by the second member 140. However, the greater part of the light emitted by the semiconductor structure body 121 may undergo wavelength conversion by the second member 140, and the light that is emitted from the light-emitting device 12 may be mainly the light emitted by the second member 140. The wavelength conversion material can include, for example, phosphor particles. As the phosphor, an yttrium-aluminum-garnet-based phosphor (e.g., Y₃(Al, Ga)₅O₁₂:Ce), a lutetium-aluminum-garnet-based phosphor (e.g., Lu₃(Al, Ga)₅O₁₂:Ce), a terbium-aluminum-garnet-based phosphor (e.g., Tb₃(Al, Ga)₅O₁₂:Ce), a CCA-based phosphor (e.g., Ca₁₀(PO₄)₆Cl₂: Eu), an SAE-based phosphor (e.g., Sr₄Al₁₄O₂₅: Eu), a chlorosilicate-based phosphor (e.g., CaₛMgSi₄O₁₆Cl₂:Eu), an oxynitride-based phosphor such as a β-sialon-based phosphor (e.g., (Si, AI)₃(O, N)₄:Eu), an α-sialon-based phosphor (e.g., Ca(Si, AI)₁₂(O, N)₁₆:Eu), or the like, a nitride-based phosphor such as an SLA-based phosphor (e.g., SrLiAl₃N₄: Eu), a CASN-based phosphor (e.g., CaAlSiN₃: Eu), a SCASN-based phosphor (e.g., (Sr, Ca)AlSiN₃:Eu), or the like, a fluoride-based phosphor such as a KSF-based phosphor (e.g., K₂SiF₆: Mn), a KSAF-based phosphor (e.g., K₂Si_{0.99}Al_{0.01}F_{5.99}:Mn), a MGF-based phosphor (e.g., 3.5MgO·0.5MgF₂·GeO₂:Mn), or the like, a phosphor having a perovskite structure (e.g., CsPb(F, Cl, Br, I)₃), a quantum dot phosphor (e.g., CdSe, InP, AgInS₂, or AgInSe₂), etc., can be used.

The thickness of the second member 140 is greater than the thickness of the first member 130. The thickness of the second member 140 can be, for example, not less than 30 µm and not more than 200 µm.

The first member 130 is located between the semiconductor structure body 121 and the second member 140. According to the embodiment, the first member 130 covers substantially the entire region of the first surface 121s1 of the semiconductor structure body 121 and the lower surface 142 of the second member 140. Specifically, the first member 130 is located inside the recesses 121a of the first surface 121s1 of the semiconductor structure body 121 and on the region 121b between the multiple recesses 121a. In the Z-direction, the first member 130 covers the region of the lower surface 142 of the second member 140 positioned outward of the first surface 121s1 of the semiconductor structure body 121.

The first member 130 includes a resin member 131 that is transmissive. Here, “transmissive” means transmissive to not less than 70%, and favorably not less than 80% of the incident light. The resin member 131 is formed by curing an uncured resin. The resin member 131 can include a thermosetting resin, a resin cured by irradiating ultraviolet light, etc. According to the embodiment, the hardness of the second member 140 is greater than the hardness of the resin member 131 in the cured state. However, the magnitude relationship between the hardness of the second member 140 and the hardness of the resin member 131 in the cured state is not limited to such a magnitude relationship.

The first member 130 further includes a wavelength conversion material 132 located inside the resin member 131. The wavelength conversion material 132 of the first member 130 can include the same wavelength conversion material used in the second member 140. However, the wavelength conversion material 132 may be omitted from the first member 130.

The thickness of the first member 130 can be, for example, not less than 10 µm and not more than 100 µm. The thickness of the first member 130 located in the recess 121a is less than the thickness of the first member 130 located at a region 121b1. The thickness of the first member 130 located in the recess 121a is, for example, not less than 1 µm and not more than 10 µm. The thickness of the first member 130 located at the region 121b1 is, for example, not less than 3 µm and not more than 50 µm.

The resin member 13 is located on the wiring substrate 11. The resin member 13 surrounds the light-emitting device 12 when viewed along the Z-direction. Specifically, the resin member 13 covers the lateral surface 121s3 of the semiconductor structure body 121 of the light-emitting element 120, the regions of the lateral surface and the lower surface of the exposed first member 130, and the lateral surface of the second member 140. As shown in FIG. 2B, the resin member 13 surrounds the insulating film 123 and the n-side electrode 124 of the light-emitting element 120 when viewed along the Z-direction.

The resin member 13 is light-reflective. The resin member 13 includes, for example, a light-diffusing material that can diffusely reflect the light emitted by the second member 140. For example, a silicone resin, an epoxy resin, an acrylic resin, etc., are examples of the resin included in the resin member 13. For example, particles of titania, silica, alumina, zinc oxide, magnesium oxide, zirconia, yttria, calcium fluoride, magnesium fluoride, niobium pentoxide, barium titanate, tantalum pentoxide, barium sulfate, glass, etc., are examples of the light-diffusing agent included in the resin member 13.

However, the configuration of the light-emitting module 10 is not limited to the configuration described above. For example, the light-emitting module 10 may include multiple light-emitting devices 12. In such a case, the resin member 13 may be provided to surround each light-emitting device 12. The light-emitting module 10 may include the light-emitting device 12 and the resin member 13 without the wiring substrate 11.

An example of a method for manufacturing the light-emitting module 10 including the light-emitting device 12 according to the embodiment will now be described.

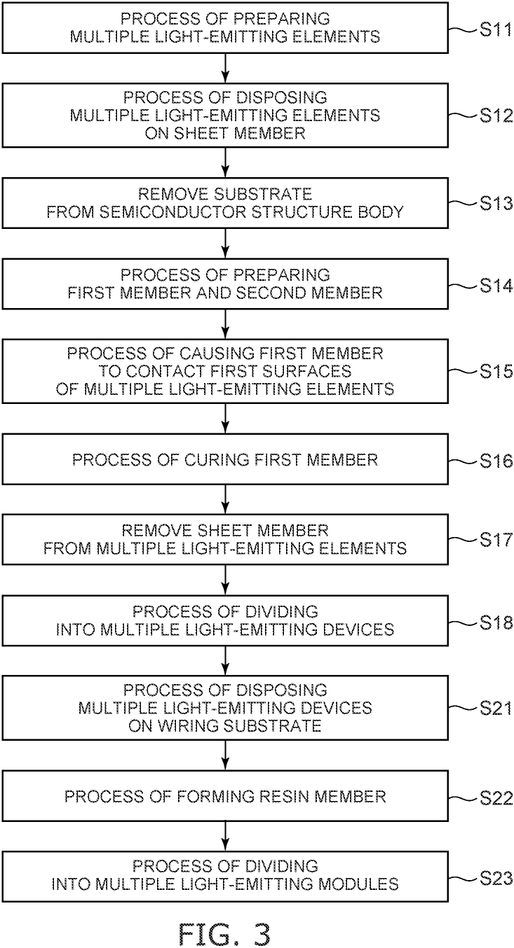

FIG. 3 is a flowchart showing the method for manufacturing the light-emitting module 10 according to the embodiment.

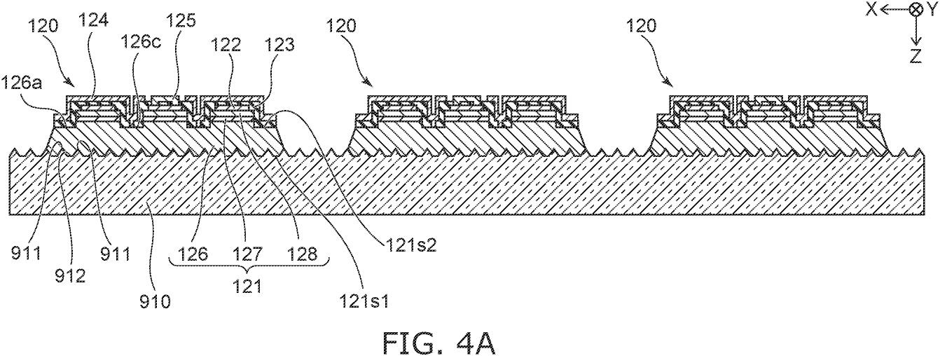

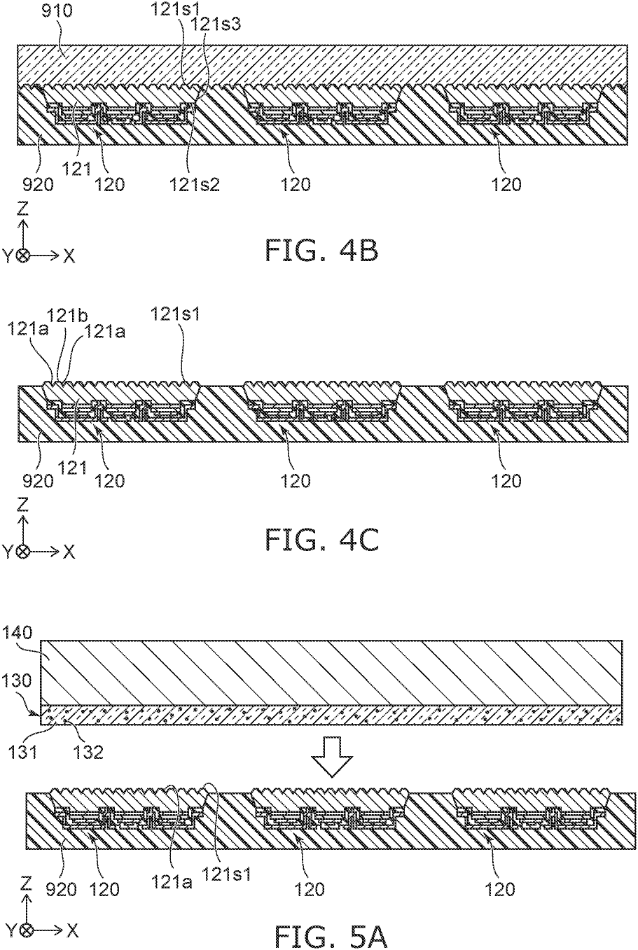

FIGS. 4A to 7C are cross-sectional views illustrating the method for manufacturing the light-emitting module 10 according to the embodiment.

As shown in FIG. 3, the method for manufacturing the light-emitting device 12 according to the embodiment includes a step S11 of preparing the multiple light-emitting elements 120, a step S12 of disposing the multiple light-emitting elements 120 on the sheet member 920, a step S13 of removing a substrate 910 from the semiconductor structure body 121, a step S14 of preparing the first member 130 and the second member 140, a step S15 of causing the first member 130 to contact the first surfaces 121s1 of the multiple light-emitting elements 120, a step S16 of curing the first member, a step S17 of removing the sheet member 920 from the multiple light-emitting elements 120, and a step S18 of dividing into the multiple light-emitting devices 12. The steps S11 to S18 will now be elaborated.

First, the step S11 of preparing the multiple light-emitting elements 120 is performed.

Specifically, as shown in FIG. 4A, the semiconductor structure body 121 is epitaxially grown on the substrate 910 including multiple protrusions 911 in the surface. At this time, the n-side semiconductor layer 126, the active layer 127, and the p-side semiconductor layer 128 are formed in this order. The surface of the semiconductor structure body 121 facing the substrate 910 is the first surface 121s1.

The substrate 910 is, for example, a transmissive substrate such as a sapphire substrate, etc. The multiple protrusions 911 are arranged in a staggered configuration. Each protrusion 911 is substantially circular conic. A region 912 between the multiple protrusions 911 at the surface of the substrate 910 is substantially parallel to the X-Y plane. Therefore, the first surface 121s1 includes the multiple recesses 121a that correspond to the multiple protrusions 911. The region 121b of the first surface 121s1 between the multiple recesses 121a is substantially parallel to the X-Y plane to correspond to the region 912 between the multiple protrusions 911 of the substrate 910. However, the arrangement pattern of the multiple protrusions is not limited to the arrangement pattern described above. For example, multiple protrusions may be arranged in a matrix configuration. The shape of each protrusion is not particularly limited to such shapes. For example, each protrusion may be a truncated pyramid, circular cone, polygonal pyramid, hemisphere, etc.

Then, the multiple contact regions 126c and the outer perimeter region 126a of the n-side semiconductor layer 126 are exposed from under the active layer 127 and the p-side semiconductor layer 128 by etching a portion of the semiconductor structure body 121.

Continuing, the light-reflective electrode 122 is formed on the p-side semiconductor layer 128. Then, the insulating film 123 is formed to cover the semiconductor structure body 121. Then, the n-side electrode 124 that is positioned on the insulating film 123 and electrically connected with the n-side semiconductor layer 126 and the p-side electrode 125 that is positioned on the insulating film 123 and electrically connected with the p-side semiconductor layer 128 are formed. Then, the structure is divided into the multiple light-emitting elements 120 by exposing the substrate 910 by removing the semiconductor structure body 121 positioned between the regions used to form the light-emitting element 120. Thus, the multiple light-emitting elements 120 are obtained. The sequence of the sub-steps in the step of preparing the multiple light-emitting elements 120 is not particularly limited to the sequence described above.

Then, the step S12 of disposing the multiple light-emitting elements 120 on the sheet member 920 is performed.

Specifically, as shown in FIG. 4B, the multiple light-emitting elements 120 are disposed on the adhesive sheet member 920 so that the second surfaces 121s2 of the light-emitting elements 120 face the sheet member 920 and so that the lateral surfaces 121s3 of the light-emitting elements 120 are covered with the sheet member 920. At this time, the multiple light-emitting elements 120 may be buried inside the sheet member 920, and the substrate 910 may contact the sheet member 920.

The sheet member 920 can include a material that is heat-resistant and adhesive such as polyimide, etc.

Then, as shown in FIG. 4C, the step S13 of removing the substrate 910 from the semiconductor structure body 121 is performed. Examples of methods of removing the substrate 910 from the semiconductor structure body 121 include, for example, laser lift-off (LLO) in which the substrate 910 is removed from the semiconductor structure body 121 by irradiating a laser from the substrate 910 side to concentrate the laser at the vicinity of the interface between the semiconductor structure body 121 and the substrate 910, etc. The first surface 121s1 of the semiconductor structure body 121 is exposed thereby. Thus, the surface of the semiconductor structure body 121 exposed by removing the substrate 910 is the first surface 121s1. The first surface 121s1 may be cleaned with hydrochloric acid, etc. The first surface 121s1 may be roughened by wet etching. The light extraction efficiency can be increased by roughening the first surface 121s1.

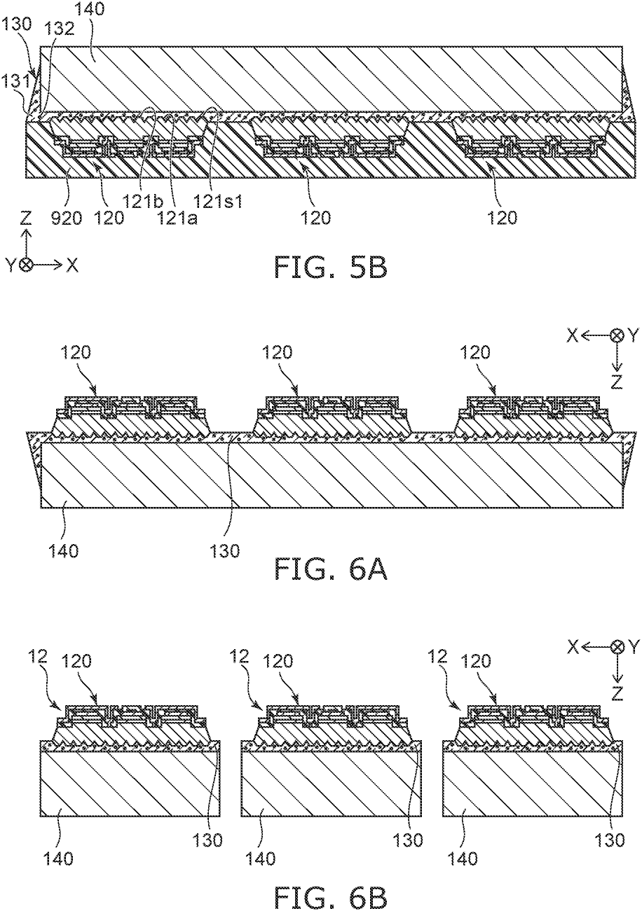

Continuing, the step S14 of preparing the first member 130 and the second member 140 is performed. Specifically, as shown in FIG. 5A, the second member 140 that includes a wavelength conversion material and has a higher hardness than the uncured resin member 131 is disposed on the first member 130 that includes the transmissive uncured resin member 131. According to the embodiment, the wavelength conversion material 132 is located inside the uncured resin member 131. The hardness of the second member 140 is, for example, a Vickers hardness of not less than 10 GPa and not more than 20 GPa. Here, “uncured” refers to the state before a curing reaction progresses, that is, the state before an operation for causing the curing reaction to progress is performed. Examples of operations for causing the curing reaction to progress include heating, light irradiation, etc. Although there are cases where the curing reaction slightly progresses before the operation for causing the curing reaction to progress, the uncured state also includes such a state.

Then, as shown in FIGS. 5A and 5B, the step S15 of causing the first member 130 to contact the first surfaces 121s1 of the multiple light-emitting elements 120 is performed. Specifically, the first member 130 is caused to contact the first surfaces 121s1 of the multiple light-emitting elements 120 so that the first member 130 is located inside the multiple recesses 121a and located between the sheet member 920 and the second member 140. At this time, the first member 130 is interposed between the second member 140 and the region 121b between the multiple recesses 121a.

At this time, the first member 130 is caused to contact the first surface 121s1 in a heated state. For example, the first member 130 is caused to contact the first surface 121s1 and is pressed onto the first surface 121s1. Thereby, the first member 130 easily flows, and the first member 130 is easily disposed inside the recesses 121a. For example, the first member 130 is brought to the heated state by placing the members on a hotplate and heating, and then a load is applied. The temperature when heating can be, for example, not less than 150° C. and not more than 200° C. The applied load can be, for example, not less than 70 N and not more than 150 N. It is sufficient to perform the step S14 of preparing the first member 130 and the second member 140 before the step S15 of the contact, and it is unnecessary to perform the step S14 after the step S13 of removing the substrate 910 from the semiconductor structure body 121.

Then, the step S16 of curing the first member 130 is performed. The hardness of the first member 130 after curing is, for example, a Vickers hardness of not less than 0.5 GPa and not more than 2 GPa.

Continuing as shown in FIG. 6A, the step S17 of removing the sheet member 920 from the multiple light-emitting elements 120 is performed.

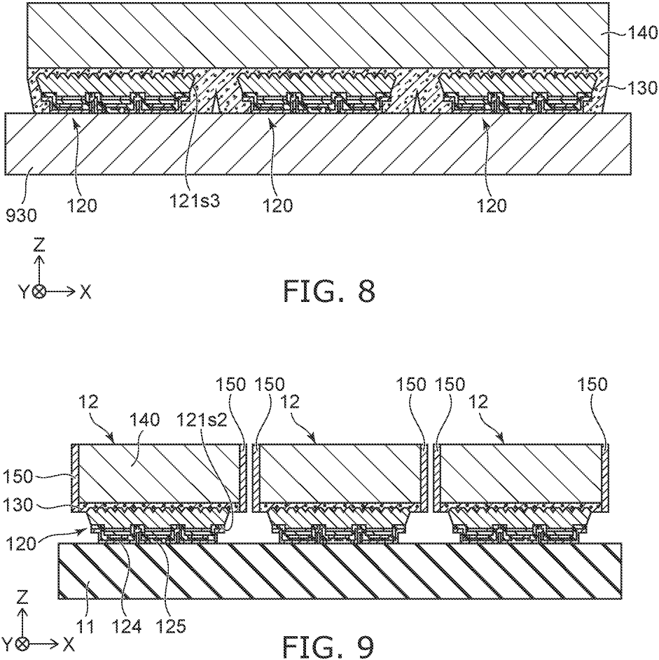

Here, a method for manufacturing a reference example will be described with reference to FIG. 8.

FIG. 8 is a cross-sectional view illustrating a method for manufacturing a light-emitting module according to the reference example. In the reference example, the first member 130 contacts the multiple light-emitting elements 120 located on a support substrate 930 instead of the sheet member 920.

As shown in FIG. 8, when the multiple light-emitting elements 120 are located on the support substrate 930 instead of the sheet member 920, the lateral surfaces 121s3 of the light-emitting elements 120 are not covered with the support substrate 930. When the second member 140 is caused to contact the multiple light-emitting elements 120 in this state, a portion of the first member 130 is pushed out from between the second member 140 and the light-emitting elements 120 and contacts the lateral surfaces 121s3. In such a case, the first member 130 that is pushed out may flow over the lateral surfaces 121s3 of the light-emitting elements 120 and adhere to the support substrate 930. When the first member 130 is cured while a portion of the first member 130 is adhered to the support substrate 930, the first member 130 is adhered to the support substrate 930, and it may be difficult to remove the support substrate 930 from the multiple light-emitting elements 120 by peeling, etc. Also, there is a possibility that the multiple light-emitting elements 120 and the second member 140 may be damaged when forcibly removing the support substrate 930 from the multiple light-emitting elements 120.

In contrast, according to the embodiment as shown in FIG. 5B, the multiple light-emitting elements 120 are located on the sheet member 920, and the sheet member 920 covers the lateral surfaces 121s3 of the multiple light-emitting elements 120. Therefore, the portion of the first member 130 pushed out when the second member 140 is caused to contact the multiple light-emitting elements 120 flows around to the lateral surface of the second member 140 without flowing over the lateral surfaces 121s3 of the semiconductor structure bodies 121. In other words, the part of the first member 130 that is pushed out covers at least a portion of the lateral surface of the second member 140. Thus, the first member 130 that is adhered to the lateral surfaces 121s3 of the semiconductor structure bodies 121 can be reduced. Therefore, the sheet member 920 can be more easily removed from the multiple light-emitting elements 120 by peeling, etc. As a result, damage of the multiple light-emitting elements 120 and the second member 140 when removing the sheet member 920 can be reduced. It is favorable for the sheet member 920 to be flexible. Thereby, the sheet member 920 can be easily removed from the multiple light-emitting elements 120.

Then, as shown in FIG. 6B, the step S18 of dividing into the multiple light-emitting devices 12 is performed. Specifically, the first member 130 and the second member 140 that are positioned between the multiple light-emitting elements 120 in a top-view are removed using a cutting machine such as a dicing saw, etc. The multiple light-emitting devices 12 that each include the light-emitting element 120, the first member 130, and the second member 140 are obtained thereby.

After the step S18, as shown in FIG. 3, a step S21 of disposing the multiple light-emitting devices 12 on the wiring substrate 11, a step S22 of forming the resin member 13, and a step S23 of dividing into the multiple light-emitting modules 10 may be performed. The steps S21 to S23 will now be elaborated.

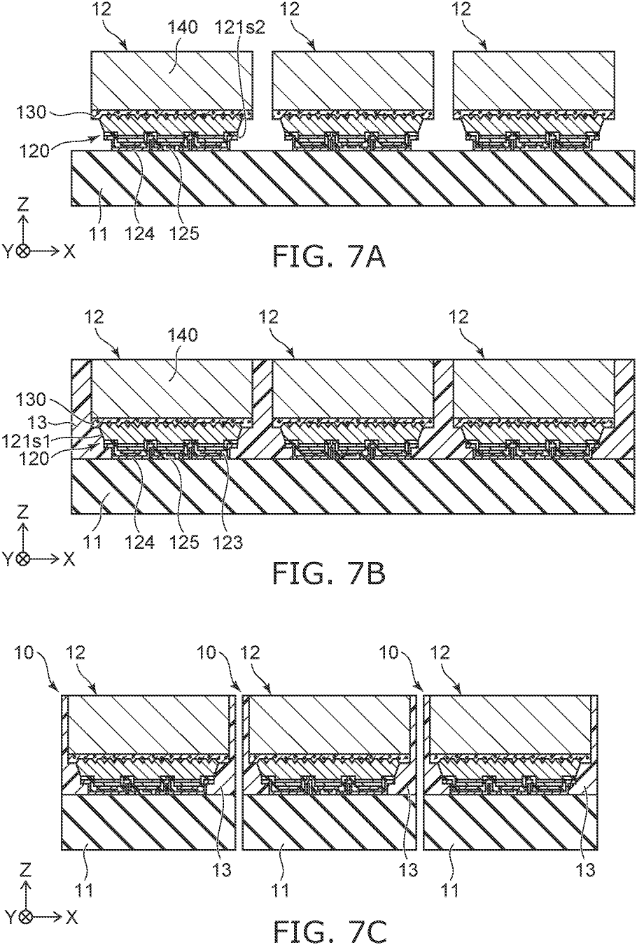

In the step S21 of disposing the multiple light-emitting devices 12 on the wiring substrate 11 as shown in FIG. 7A, the light-emitting devices 12 are disposed so that the wiring substrate 11 and the second surfaces 121s2 of the light-emitting elements 120 face each other. The n-side electrode 124 of each light-emitting element 120 and one interconnect of the wiring substrate 11 are connected by a conductive member. Also, the p-side electrode 125 of each light-emitting element 120 and another interconnect of the wiring substrate 11 are connected by a conductive member. Thereby, the light-emitting elements 120 are flip-chip mounted to the wiring substrate 11.

As shown in FIG. 9, a reflecting member 150 may be formed on the lateral surface of the first member 130 and the lateral surface of the second member 140. FIG. 9 is a cross-sectional view illustrating the method for manufacturing the light-emitting module according to a modification of the embodiment. The reflecting member 150 is a member for reflecting the light from the first and second members 130 and 140. The reflecting member 150 can include, for example, aluminum, nickel, titanium, platinum, an alloy that includes such a metal as a major component, etc. The reflecting member 150 may include a dielectric multilayer film that includes multiple dielectric layers. When such a reflecting member 150 is formed, the step of forming the resin member 13 may be omitted.

Then, as shown in FIG. 7B, the step S22 of forming the resin member 13 is performed. Specifically, the light-reflective resin member 13 is formed to cover the lateral surface 121s3 of the light-emitting element 120, the exposed regions of the lateral surface and the lower surface of the first member 130, and the lateral surface of the second member 140. For example, in the step S22 of forming the resin member 13, the resin member 13 is formed by forming a resin material to cover the upper surface of the second member 140 and then by exposing the upper surface of the second member 140 from under the resin material by removing a portion of the resin material. By reducing the amount of the first member 130 adhered to the lateral surface 121s3 of the light-emitting element 120 in the step S15 of the contact, the resin member 13 can be formed to cover the lateral surface 121s3 of the light-emitting element 120. The resin member 13 is connected not only to the second member 140 that is the sintered body of the wavelength conversion material but also to the first member 130 that includes the resin member 131. Therefore, the bonding strength between the resin member 13 and the light-emitting device 12 can be increased.

Continuing as shown in FIG. 7C, the step S23 of dividing into multiple light-emitting modules is performed. Specifically, the resin member 13 and the wiring substrate 11 that are positioned between the multiple light-emitting devices 12 in a top-view are removed using a cutting machine such as a dicing saw, etc. The multiple light-emitting modules 10 that each include the wiring substrate 11, the light-emitting device 12, and the resin member 13 are obtained thereby. However, a module that includes the wiring substrate 11, the multiple light-emitting devices 12, and the resin member 13 shown in FIG. 7B may be used as the light-emitting module 10 without performing the step S23. Also, in the step S21, instead of the wiring substrate 11, the multiple light-emitting devices 12 may be disposed on a support substrate that does not include interconnects, and the support substrate may be removed from the multiple light-emitting devices 12 after the step S22 of forming the resin member 13.

A usage example of the light-emitting module 10 will now be described.

The active layer 127 is caused to emit light by applying a voltage between the n-side electrode 124 and the p-side electrode 125 of the light-emitting element 120 via the wiring substrate 11. The greater part of the light emitted by the active layer 127 is incident on the second member 140. Therefore, the second member 140 emits light. According to the embodiment, the first member 130 includes the wavelength conversion material 132; therefore, the wavelength conversion material 132 of the first member 130 also emits light.

Effects of the embodiment will now be described.

The method for manufacturing the light-emitting device 12 according to the embodiment includes the step S11 of preparing the multiple light-emitting elements 120, the step S12 of disposing the multiple light-emitting elements 120 on the sheet member 920, the step S15 of causing the first member 130 to contact the first surfaces 121s1 of the multiple light-emitting elements 120, the step S16 of curing the first member 130, and the step S17 of removing the sheet member 920 from the multiple light-emitting elements 120. In the step S11, the multiple light-emitting elements 120 that include the semiconductor structure bodies 121 that includes the first surfaces 121s1 including the multiple recesses 121a, the second surfaces 121s2 positioned at the side opposite to the first surfaces 121s1, and the lateral surfaces 121s3 connecting the first surfaces 121s1 and the second surfaces 121s2 are prepared. In the step S12, the second surfaces 121s2 of the light-emitting elements 120 are caused to face the adhesive sheet member 920, and the multiple light-emitting elements 120 are disposed on the sheet member 920 so that the lateral surfaces 121s3 of the light-emitting elements 120 are covered with the sheet member 920. In the step S15, the first member 130 is caused to contact the first surfaces 121s1 of the multiple light-emitting elements 120 so that the first member 130 is located inside the multiple recesses 121a and located between the sheet member 920 and the second member 140 in a state in which the second member 140 that includes a wavelength conversion material and has a higher hardness than the uncured resin member 131 is located on the first member 130 that includes the transmissive uncured resin member 131.

Thus, according to the method for manufacturing the light-emitting device 12 according to the embodiment, the substrate 910 that is used to epitaxially grow the semiconductor structure body 121 is not located between the light-emitting element 120 and the second member 140, and the second member 140 and the semiconductor structure body 121 of the light-emitting element 120 are connected by the first member 130. Therefore, the light extraction efficiency of the light-emitting device 12 can be increased.

The multiple recesses 121a are provided in the first surface 121s1. Therefore, the total internal reflections at the first surface 121s1 of the light emitted by the active layer 127 can be reduced. Thereby, the light that is emitted by the active layer 127 is easily incident on the second member 140, and the light extraction efficiency of the light-emitting device 12 can be increased.

The first member 130 is caused to contact the multiple light-emitting elements 120 in a state in which the lateral surfaces 121s3 of the light-emitting elements 120 are covered with the sheet member 920. Therefore, the amount of the first member 130 adhered to the lateral surfaces 121s3 of the light-emitting elements 120 can be reduced. The sheet member 920 can be easily removed thereby. As a result, damage of the second member 140 when removing the sheet member 920 can be reduced, and the yield can be increased.

In the step S11 of the preparation, the semiconductor structure body 121 is epitaxially grown on the substrate 910 that includes the multiple protrusions 911 in the surface of the substrate 910. The step S13 of removing the substrate 910 from the semiconductor structure body 121 is further included before the step S15 of the contact. In the step S13 of removing the substrate 910 from the semiconductor structure body 121, the surface of the semiconductor structure body 121 that is exposed by removing the substrate 910 is the first surface 121s1, and the shape of the multiple recesses 121a of the first surface 121s1 corresponds to the multiple protrusions 911. It is therefore unnecessary to pattern the surface of the semiconductor structure body 121 to form the multiple recesses 121a after removing the substrate 910, and the steps can be simplified.

The first surface 121s1 includes the region 121b positioned between the multiple recesses 121a. In the step S15 of the contact, the first member 130 is caused to contact the first surface 121s1 so that the first member 130 is interposed between the second member 140 and the region 121b. Therefore, the light-emitting element 120 can be securely adhered to the second member 140 via the first member 130.

The second member 140 is a sintered body of a wavelength conversion material. Therefore, the hardness of the second member 140 can be higher than when the second member 140 includes a resin member and a wavelength conversion material inside the resin member. The deformation of the second member 140 in the step S15 of the contact and the step S17 of removing the sheet member 920 from the multiple light-emitting elements 120 can be reduced thereby.

In the step S15 of the contact, the first member 130 is caused to contact the first surface 121s1 in a heated state. The fluidity of the first member 130 is increased thereby, and the first member 130 is easily disposed inside the recesses 121a of the semiconductor structure body 121.

The first member 130 includes the wavelength conversion material 132. Thereby, the light conversion efficiency of the wavelength conversion material can be higher than when only the second member 140 includes the wavelength conversion material.

Also, the step S18 of dividing into the multiple light-emitting devices 12 by removing the first member 130 and the second member 140 positioned between the multiple light-emitting elements 120 in a top-view is performed after the step S16 of curing the first member 130. Thus, the light-emitting devices 12 can be manufactured with a high yield by dividing into the multiple light-emitting devices 12 after the multiple light-emitting elements 120 are connected to the second member 140 via the first member 130.

Also, a step S19 of forming the light-reflective resin member 13 to cover the lateral surface 121s3 of the light-emitting element 120, the lateral surface of the first member 130, and the lateral surface of the second member 140 is performed after the step S18 of dividing into the multiple light-emitting devices 12. Therefore, the light traveling toward the lateral surfaces 121s3 of the light-emitting elements 120 is reflected toward the second member 140 by the resin member 13. The light extraction efficiency of the light-emitting device 12 can be increased thereby. The resin member 13 is connected not only to the second member 140, i.e., the sintered body of the wavelength conversion material, but also to the first member 130 that includes the resin member 131. The bonding strength between the resin member 13 and the light-emitting device 12 can be increased thereby.

The first member 130 is caused to contact the lateral surface of the second member 140 in the step S15 of the contact. Specifically, in the step S15 of the contact, the second member 140 is caused to contact the multiple light-emitting elements 120 in a state in which the lateral surfaces 121s3 of the light-emitting elements 120 are covered with the sheet member 920. Thereby, a portion of the first member 130 is pushed out from between the light-emitting element 120 and the second member 140 while the first member 130 is located inside the multiple recesses 121a so that the portion of the first member 130 contacts the lateral surface of the second member 140. The bonding strength between the first member 130 and the second member 140 can be increased thereby, while reducing the portion of the first member 130 that is pushed out to be adhered to the lateral surfaces 121s3 of the light-emitting elements 120.

### Second Embodiment

A second embodiment will now be described.

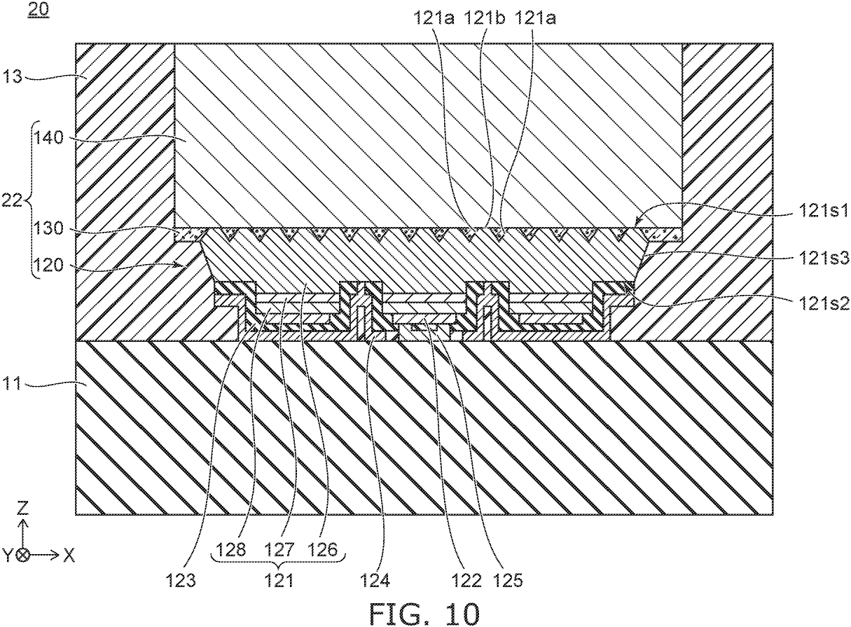

FIG. 10 is a cross-sectional view showing a light-emitting module 20 according to the embodiment.

As a general rule in the following description, only the differences with the first embodiment are described. Other than the items described below, the embodiment is similar to the first embodiment.

A light-emitting device 22 of the light-emitting module 20 according to the embodiment differs from the light-emitting device 12 according to the first embodiment in that the second member 140 contacts the region 121b between the multiple recesses 121a at the first surface 121s1. Such a light-emitting device 22 can be obtained by causing the second member 140 to approach the multiple light-emitting elements 120 until the second member 140 contacts the first surface 121s1 in the step S15 of the contact according to the first embodiment.

Effects of the embodiment will now be described.

The first surface 121s1 includes the region 121b positioned between the multiple recesses 121a, and in the step S15 of the contact, the first member 130 is caused to contact the first surface 121s1 so that the second member 140 contacts the region 121b. Therefore, fluctuation between positions along the X-Y plane of the distance between the second member 140 and the light-emitting element 120 can be reduced. By causing the second member 140 to contact the region 121b, the heat dissipation can be improved because the heat dissipation path from the second member 140 toward the semiconductor structure body 121 can be better ensured than when the first member 130 is located between the second member 140 and the region 121b.

What is claimed is:

1. A method for manufacturing a light-emitting device, the method comprising:
preparing a plurality of light-emitting elements, each of the plurality of light-emitting elements comprising a semiconductor structure body that comprises:
a first surface including a plurality of recesses,
a second surface positioned at a side opposite to the first surface, and
a lateral surface connecting the first surface and the second surface;
disposing the plurality of light-emitting elements on a sheet member so that the second surfaces of the semiconductor structure bodies face the sheet member and so that the lateral surfaces of the semiconductor structure bodies are covered with the sheet member, the sheet member being adhesive;
causing a first member to contact the first surfaces of the semiconductor structure bodies so that the first member is located inside the plurality of recesses and located between the sheet member and a second member in a state in which the second member is located on the first member, the first member comprising an uncured resin member that is transmissive, the second member comprising a wavelength conversion material and having a higher hardness than the uncured resin member;
curing the first member; and
removing the sheet member from the plurality of light-emitting elements.

2. The method according to claim 1, wherein:
the step of preparing the plurality of light-emitting elements comprises epitaxially growing the semiconductor structure body on a substrate, a surface of the substrate including a plurality of protrusions;
the method further comprises, before the step of causing the first member to contact the first surfaces of the semiconductor structure bodies, removing the substrate from the semiconductor structure body so as to expose the first surface of the semiconductor structure body; and
a shape of the plurality of recesses of the first surface corresponds to a shape of the plurality of protrusions.

3. The method according to claim 1, wherein:
the first surface includes a region positioned between the plurality of recesses; and
in the step of causing the first member to contact the first surfaces of the semiconductor structure bodies, the first member is caused to contact the first surface so that the first member is interposed between the second member and the region of the first surface.

4. The method according to claim 2, wherein:
the first surface includes a region positioned between the plurality of recesses; and
in the step of causing the first member to contact the first surfaces of the semiconductor structure bodies, the first member is caused to contact the first surface so that the first member is interposed between the second member and the region of the first surface.

5. The method according to claim 1, wherein:
the first surface includes a region positioned between the plurality of recesses; and
in the step of causing the first member to contact the first surfaces of the semiconductor structure bodies, the first member is caused to contact the first surface so that the second member contacts said region of the first surface.

6. The method according to claim 2, wherein:
the first surface includes a region positioned between the plurality of recesses; and
in the step of causing the first member to contact the first surfaces of the semiconductor structure bodies, the first member is caused to contact the first surface so that the second member contacts said region of the first surface.

7. The method according to claim 3, wherein:
the first surface includes a region positioned between the plurality of recesses; and
in the step of causing the first member to contact the first surfaces of the semiconductor structure bodies, the first member is caused to contact the first surface so that the second member contacts said region of the first surface.

8. The method according to claim 1, wherein:
the second member is a sintered body of the wavelength conversion material.

9. The method according to claim 1, wherein:
the step of causing the first member to contact the first surfaces of the semiconductor structure bodies comprises causing the first member to contact the first surface by pressing in a heated state.

10. The method according to claim 2, wherein:
the step of causing the first member to contact the first surfaces of the semiconductor structure bodies comprises causing the first member to contact the first surface by pressing in a heated state.

11. The method according to claim 3, wherein:
the step of causing the first member to contact the first surfaces of the semiconductor structure bodies comprises causing the first member to contact the first surface by pressing in a heated state.

12. The method according to claim 1, wherein:
the first member comprises a wavelength conversion material.

13. The method according to claim 1, further comprising:
after the step of curing the first member, dividing into a plurality of light-emitting devices by removing the first and second members positioned between the plurality of light-emitting elements in a top-view.

14. The method according to claim 2, further comprising:
after the step of curing the first member, dividing into a plurality of light-emitting devices by removing the first and second members positioned between the plurality of light-emitting elements in a top-view.

15. The method according to claim 3, further comprising:
after the step of curing the first member, dividing into a plurality of light-emitting devices by removing the first and second members positioned between the plurality of light-emitting elements in a top-view.

16. The method according to claim 13, further comprising:
after the step of dividing into the plurality of light-emitting devices, forming a reflective resin member to cover a lateral surface of the light-emitting element, a lateral surface of the first member, and a lateral surface of the second member.

17. The method according to claim 14, further comprising:
after the step of dividing into the plurality of light-emitting devices, forming a reflective resin member to cover a lateral surface of the light-emitting element, a lateral surface of the first member, and a lateral surface of the second member.

18. The method according to claim 15, further comprising:
after the step of dividing into the plurality of light-emitting devices, forming a reflective resin member to cover a lateral surface of the light-emitting element, a lateral surface of the first member, and a lateral surface of the second member.

19. The method according to claim 1, wherein:
the step of causing the first member to contact the first surfaces of the semiconductor structure bodies causes the first member to contact a lateral surface of the second member.

20. The method according to claim 2, wherein:
the step of causing the first member to contact the first surfaces of the semiconductor structure bodies causes the first member to contact a lateral surface of the second member.
